(19) United States
(12) Patent Application Publication
(10) Pub. No.: US 2011/0226931 A1
(43) Pub. Date: Sep. 22, 2011

(54) Portable Stand and Mount for Securing a Laptop Computer to a Support Frame

(76) Inventor: Jeffry C. Voorhees, Burbank, CA (US)

(21) Appl. No.: 13/043,444

(22) Filed: Mar. 8, 2011

Related U.S. Application Data
(63) Continuation of application No. 12/396,379, filed on Mar. 2, 2009.
(60) Provisional application No. 61/033,668, filed on Mar. 4, 2008.

(51) Int. Cl. H05K 7/00; F16M 13/00; F16M 13/02; F16B 2/06; F16M 11/04

(52) U.S. Cl. 248/636; 248/205.1; 248/229.2; 248/226.11; 248/121

(57) ABSTRACT

A portable stand and mount for securing a laptop computer. The computer is clamped between a fixed clamping member on one side and an adjustable movable clamping member on the other side. The movable clamping member is positioned by screw means mounted on the top surface of the mounting plate of the stand. The mounting plate also is provided with a plurality of holes that allow the clamping members to be positioned to accommodate various sizes and configurations of laptop computers. It also is provided with openings which allow cooling air to circulate beneath the computer, with means for hanging accessories therefrom, and with a light. A mounting post extends downwardly from the underside of the mounting plate, so that it can be clamped to other fixtures such as a drum set stand or tripod.

### CROSS-REFERENCE TO RELATED APPLICATIONS

This application is a continuation of U.S. Non-provisional application Ser. No. 12/396,379, filed Mar. 2, 2009, which claims the benefit under 35 USC 119(e) of the filing date of U.S. Provisional Application Ser. No. 61/033,668, filed Mar. 4, 2008. These documents are hereby incorporated by reference in their entirety.

### FIELD OF THE INVENTION

The invention relates generally to the field of securing a laptop computer to a support frame in such a manner as to allow the user to operate other equipment that is attached to or in the vicinity of the support frame. It has particular use in enabling a musician to produce live and recorded music, especially when used with percussion instruments.

### DESCRIPTION OF THE PRIOR ART

Many varieties of stands, desks, and mounts for supporting a laptop computer have been produced over the years and are prevalent in the art. Some designs have been narrowed for specific locations or uses such as in vehicles and in classrooms.

These laptop support systems typically either are not portable or capable of multiple installations because they are anchored to the floor, as in a vehicle, or are free standing structures that tend to be unstable. In addition, these devices are not equipped with means for keeping the computer securely in place in case, for example, by merely providing a flat surface or an angled slope with a lip at the bottom in which the laptop rests. Others utilize straps or belts to hold the laptop in place, but these often interfere with the user's access to the keyboard and other ports and peripherals, and prevent the laptop from being fully closed.

The development of smaller and lighter computers has caused laptop computers to become an essential tool in creating music. Everything from recording and running click tracks and loops, to teaching beginners and novices how to create music with educational software applications have all been greatly improved by the use of a computer. One of the greatest contributions the use of a computer has brought to the creation of music has been the musical instrument digital interface (MIDI) system which allows electronic instruments and computers to communicate, control, and synchronize with one another to produce better a recording. Nearly all music that is recorded today uses some form of MIDI.

What is needed is a support stand and mount capable of securely and safely holding a variety of sizes of laptop computers without blocking access to any peripherals or compromising the use of the computer while being securely attached to the musician's immediate workspace, namely a musical instrument such as a drum set.

### BRIEF SUMMARY OF THE INVENTION

The present invention provides a portable stand for securing a laptop computer. It comprises a mounting plate having a top surface for receiving a laptop computer, a bottom surface, a front edge, a rear edge, and first and second side edges. An upstanding fixed clamping member is mounted on the top surface adjacent the first edge, the fixed clamping member being engageable with a first side of a laptop computer that is received on the top surface. An upstanding movable clamping member is mounted on the top surface adjacent the second edge, the movable clamping member being movable toward and away from the fixed clamping member and being engageable with a second side of a laptop computer that is received on the top surface. Adjustment means operating on the movable clamping member are provided for moving the movable clamping member toward and away from the fixed clamping member, whereby a laptop computer received on the top surface can be clamped on the top surface between the fixed clamping member and the movable clamping member.

The present invention also provides a portable stand for securing a laptop computer comprising a mounting plate having a top surface for receiving a laptop computer, a bottom surface, a front edge, a rear edge, and first and second side edges. An upstanding fixed clamping member is mounted on the top surface adjacent the first edge, the fixed clamping member being engageable with a first side of a laptop computer that is received on the top surface. A flange is mounted on the top surface adjacent the second edge, and a movable clamping member adjusting means is provided on the flange. A movable clamping member is attached to the movable clamping member adjusting means, and is movable toward and away from the fixed clamping member by the movable clamping member adjusting means. The movable clamping member is engageable with a second side of a laptop computer that is received on the top surface, whereby a laptop computer received on the top surface can be clamped on the top surface between the fixed clamping member and the movable clamping member.

### BRIEF DESCRIPTION OF THE DRAWINGS

FIG. 1 is a top plan view of the support stand on which the laptop computer is placed while being used, including the fixed and adjustable clamping members used in securing the laptop.

FIG. 2 is a bottom plan view of the support stand further depicting a support post which is used to attach the stand to a musical instrument such as a drum set, or which can be inserted into a freestanding adjustable tripod.

FIG. 3 is a right side plan view of the support stand further depicting the adjustable clamping member and the adjusting bolt with the winged bolt removed.

FIG. 4 is a left side plan view of the support stand showing the fixed clamping member.

FIG. 5 is a top plan view in enlarged scale of the side flange with winged lag bolt.

FIG. 6 is an additional top plan view of the stand depicting the flange holes, a mini-light, and an S-hook.

FIG. 7 is a left side plan view in enlarged scale of the multiple configurations for the fixed clamping member.

FIG. 8 is a right side plan view in enlarged scale of the adjustable clamping member with the adjustable knob and dual winged terminations configuration.

FIG. 9 is top plan view in enlarged scale of the adjustable clamping member with the adjustable knob configuration.

FIG. 10 is a perspective view of the inventive laptop computer support stand attached to a cymbal stand of a drum set, with a laptop computer in place.

### DETAILED DESCRIPTION OF THE PREFERRED EMBODIMENT

Computers have become an essential tool for musicians and particularly electronic percussion instruments where synthesized effects are an important performance feature. Laptop computers provide a convenient and easy way of bringing the computer and the musician closer together through the computer's smaller size and versatility. The illustrated embodiment of the invention solves the problem of maintaining a laptop close to the performer where it is needed, while still keeping it in a safe and secure location without the threat of it becoming damaged. The computer becomes in effect one of the musical instruments that the performer plays.

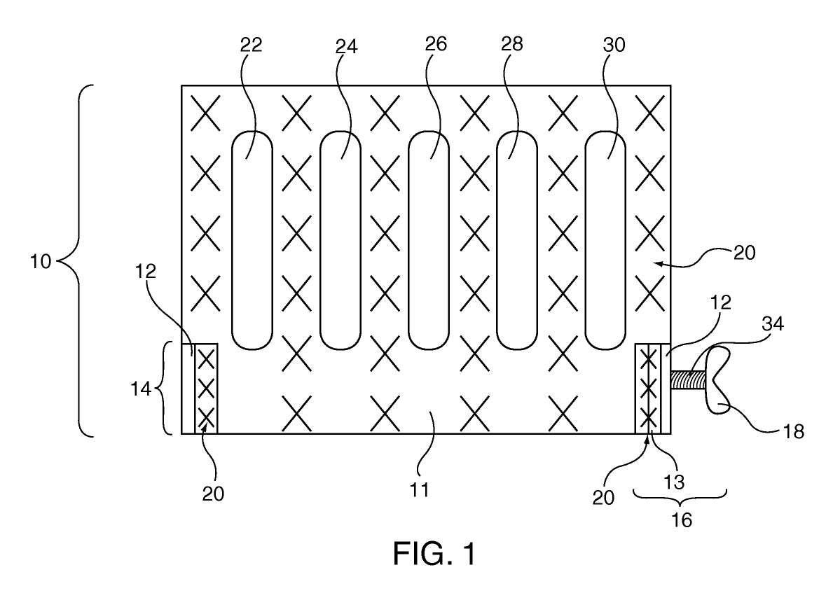

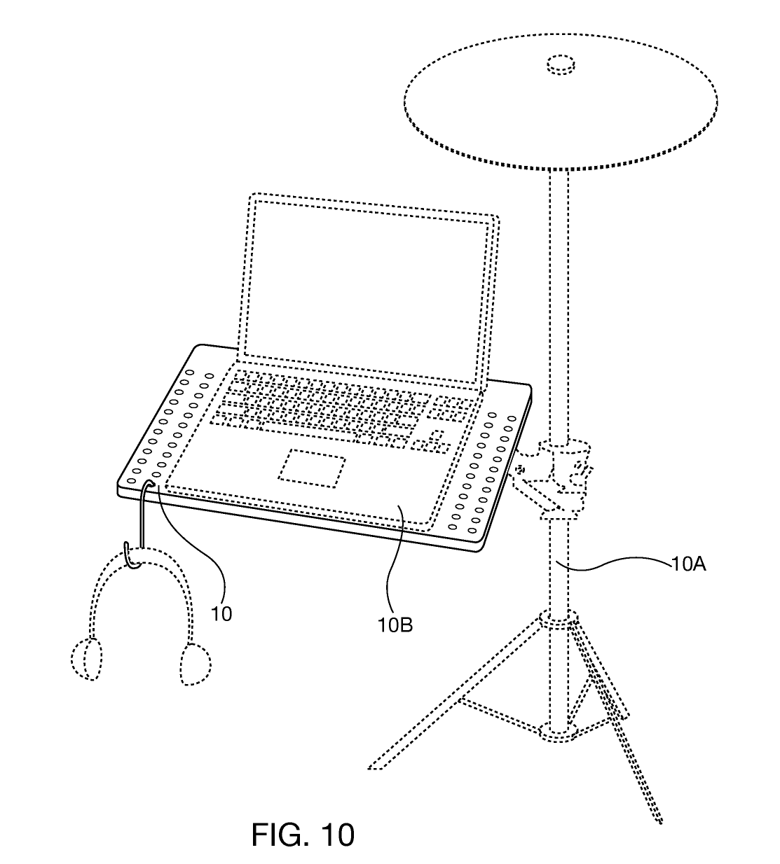

The support stand 10 of the invention is illustrated in perspective in FIG. 10 attached to a cymbal stand 10a, with a laptop computer 10b locked in position. Looking now to FIG. 1, support stand 10 is rectangular in shape and is large enough to accommodate the foot print of laptop computers that have a width of approximately 17 inches or less. Support stand 10 includes a rectangular base plate 11 comprised of a lightweight material such as aluminum, graphite or a hard plastic composite. A pair of upstanding flanges 12 are attached to the side edges of base plate 11. Flanges 12 are made of the same material as base plate 11 and can be either be coupled to the base plate 11, or are an integral extension of base plate 11 itself, e.g. base plate 11 and flanges 12 may be fabricated as a stamped sheet and then bent upward. The embodiment of FIG. 1 shows base plate 11 as extending between flanges 12, but it is also contemplated that the part of the material of base plate 11 between flanges 12 may be removed to allow air circulation to the underside of computer 10b.

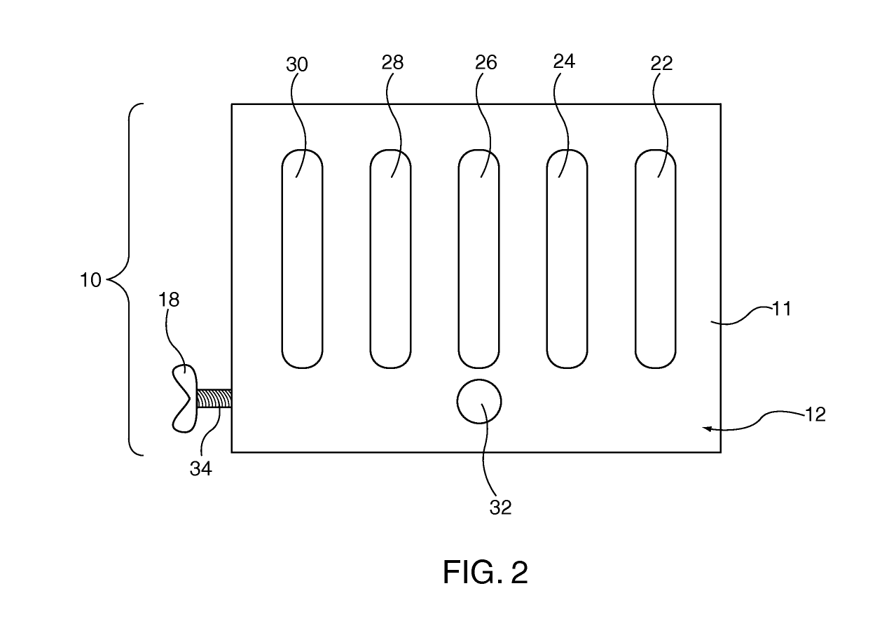

Base plate 11 also can be provided with several slots 22-30 which allow ventilation, especially for those computers that have exhaust ports on the underside. It is to be understood that although slots 22-30 have been shown as symmetrically defined into base plate 11, they may also be asymmetrically defined there through to accommodate computers of different widths or ventilation port configurations. Having a clear or unobstructed air path through the base plate 11 for these computers prevents overheating and other heat damage while the laptop is in the mounting surface. It is to be understood that the open slots 22-30 shown in FIGS. 1 and 2 are for illustrative purposes only and that any configuration, placement, and number of slots can be used without departing from the original spirit and scope of the invention.

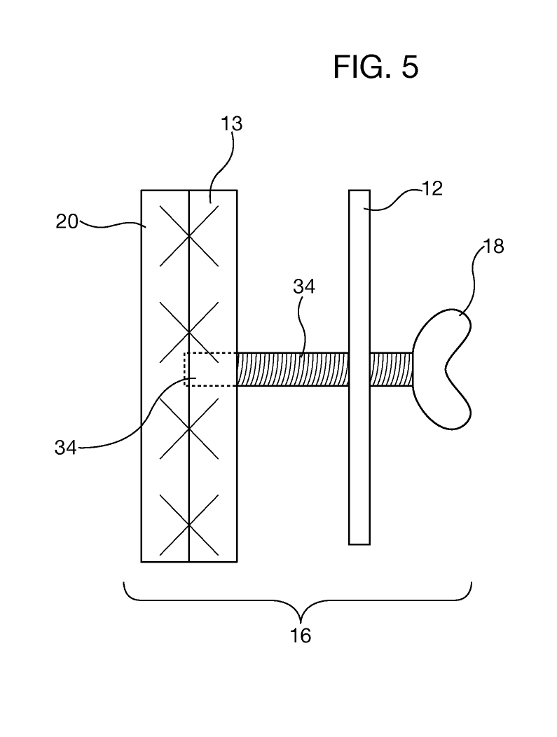

FIG. 1 further shows a non-slip rubber layer 20 disposed on the top surface of base plate 11, to provide a nonslip surface to prevent the laptop from moving or sliding on base plate 11. Non-slip rubber layer 20 may be smooth in appearance or contain small ridges or grooves which will increase the surface friction and further decrease the likelihood of slippage. The non-slip rubber layer 20 is also disposed on the inside of the elements that contact the sides of the computer. As shown in FIGS. 1 and 5, movable clamping member 13 is covered with non-slip rubber and is coupled to bolt 34, which is mounted on the right flange 12. The left side flange 12, which constitutes a fixed clamping member, has a rubber layer 20.

A similar size piece of non-slip rubber layer 20 is placed on clamping member 13 as shown in FIG. 5. A screw threaded element such as a lag bolt 34 is embedded or captured in clamping member 13 or, in another embodiment, clamping member 13 may be omitted and bolt 34 captured directly in non-slip rubber layer 20. For a laptop computer to be securely held on base plate 11, the left side of the laptop is placed against the left fixed flange 12. Adjustable right side flange 12 is then manipulated to place non-slip rubber layer 20 of the right side flange 12 against the right side of the laptop. Winged termination 18 is manually turned, advancing lag bolt 34 through right side flange 12 to clamp member 13 and layer 20 against the front edge of the laptop placed between flanges 12. It is to be expressly understood that winged termination 18 is only one of many different forms of equivalent terminations that may be used, such as a knob 44 shown in FIGS. 8 and 9, keys, levers, wheels and the like. The lag bolt 34 may be of any size as long as its threaded diameter engages a threaded hole made in material on the right side flange 12. The length of lag bolt 34 is long enough so that it reaches the right side of a laptop computer, which in the illustrated embodiment may be 12 inches across as measured from flange 12 and still has enough length left to thread the hole in right side 12 and be adjusted by winged termination 18 to snuggly clamp the computer.

The reverse side or bottom plan view of base plate 11 is shown in FIG. 2. The base plate 11 has no rubber layering underneath and is left exposed as the laptop is placed on the top of the mounting surface 10 only and no rubber is needed on the reverse side.

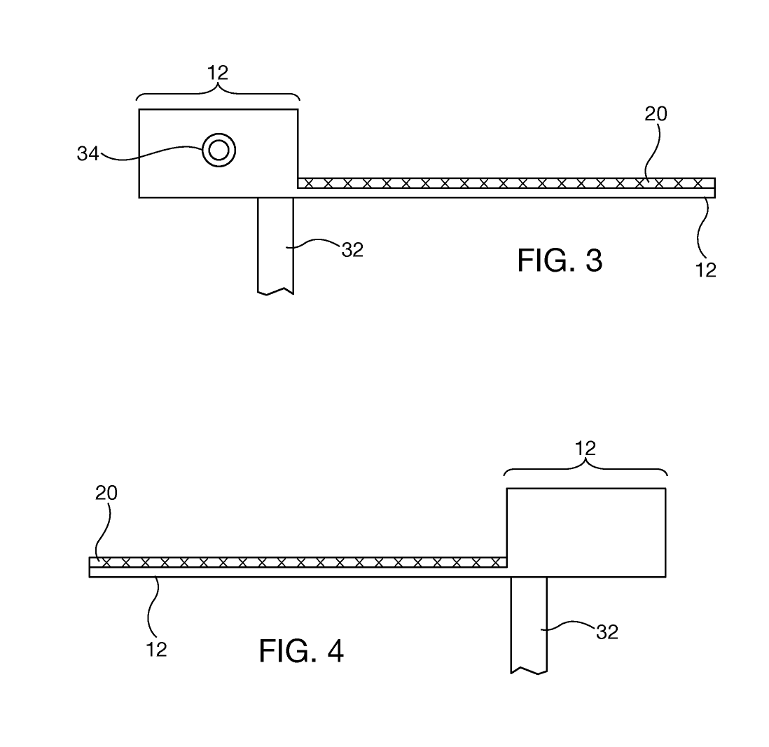

Also depicted on the reverse side of base plate 11 by FIG. 2 is the support post 32 which is used to position the mount and laptop in a fixed position in the user's immediate workspace. Support post 32 is coupled to base plate 11 by a weld or otherwise fixed to or in it, and extends vertically downward from the base plate 11 as depicted in FIGS. 3 and 4. In a separate embodiment, the support post 32 is angled at approximately 15 degrees with respect to the base plate 11 above. The angle of support post 32 may be increased or decreased as needed to increase accessibility. The angled support post 32 effectively holds the secured laptop computer at an angle which increases the accessibility of the keyboard of the computer to a user who is sitting down next to the device. The support post 32 may be made of any lightweight strong material such as aluminum or graphite and may be of any diameter sufficient enough to support the weight of the mounting surface and laptop computer without breaking or bending. It is to be expressly understood that support post 32 may be placed anywhere on the underside of base plate 11 without departing from the original spirit and scope of the invention. For example, in the preferred embodiment, support post 32 may be mounted near one edge of base plate 11 so that the distance between the distal end of support post 32 and a clamp (not shown) used to fix mount 10 to a musical instrument or drum set rail is minimized.

FIGS. 3 and 4 show the right and left side of the mount 10, respectively. These figures clearly show that non-slip rubber 20 is disposed on top of mount 10 and that support post 32 extends vertically downward. Also shown by these figures are the relative sizes of flanges 12 to the rest of the width of base plate 11. Flanges 12 do not extend along so much of the width of the base plate 11 that any of the peripheral ports or access doors normally positioned on the side of the laptop computer are obstructed. Having the peripheral ports such as the USB port, headphones jack, CD access door, and internet jack available lets the user of the mount 10 take full advantage of the capabilities of the computer and its peripherals without having to compromise for the stability that mount 10 provides.

In one embodiment of the invention, support rod 32 is coupled to a drum set via the use of a multi-clamp or double-ended clamp which is well known to those in the art. The multi-clamp attaches to support post 32 on one end and is then attached anywhere to an existing drum set or drum set rail as preferred by the user on the other end. In addition to providing a non-slip surface on the mounting surface, the rubber layer 20 also acts as a shock absorber. The rubber layer thus may be comprised of an energy-absorbing foam material in addition to having a nonslip upper surface. Shock waves caused by the drums being played will travel up support post 32 but will be decreased by the layer of rubber 20 that covers the base plate 11 and flanges 12 thus protecting the laptop computer from vibrations.

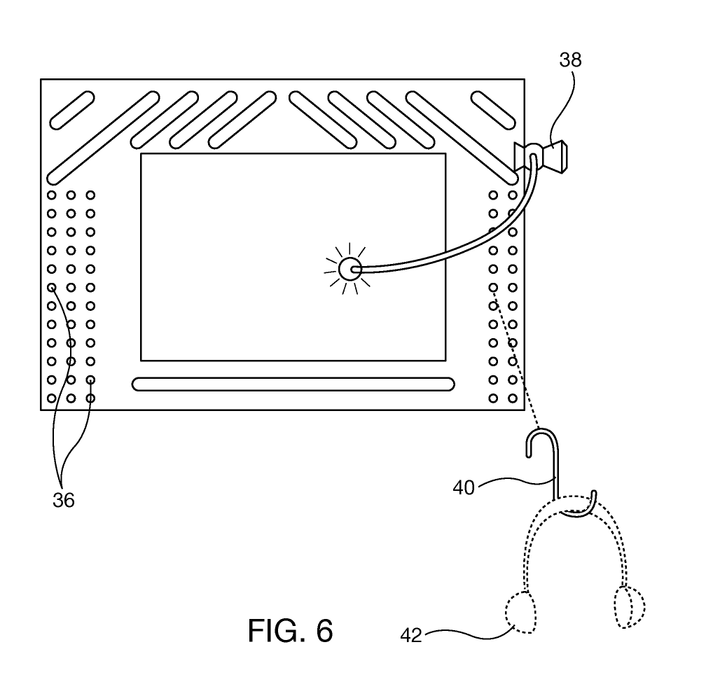

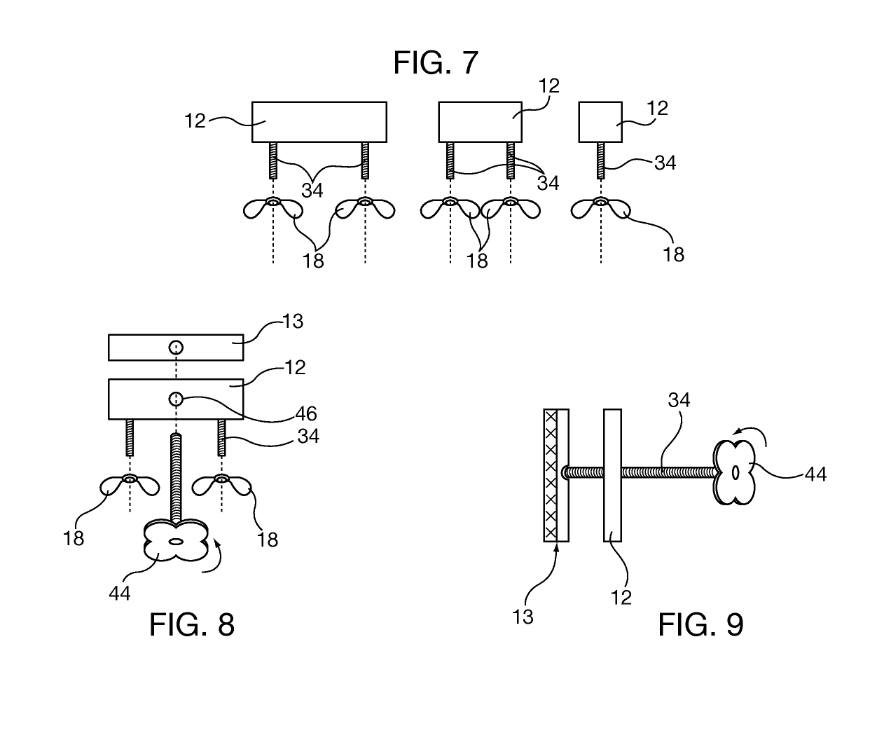

In another embodiment of the invention, multiple holes 36 are placed along the outside edges of base plate 11 as depicted in FIG. 6. Different models of laptop computers have their peripheral ports located in different positions on the unit. The holes 36 allow the flanges 12 to be detachable and be placed in any configuration along the sides of the base plate 11 according to the model of the computer that the user is employing in order to guarantee access to the desired peripheral ports. FIGS. 7 and 8 show a side view of the multiple configurations of the detachable flanges 12. Each flange 12 has at least one lag bolt 34 embedded or coupled to it. To place the detachable flanges 12 in base plate 11, the user threads the lag bolt(s) 34 through the hole(s) 36 in base plate 11. Winged termination(s) 18 are then manually tightened on the lag bolt(s) until the winged termination(s) is flush against the base plate 11, thus locking the flanges 12 into place. It is to be expressly understood that the number and location of the lag bolts 34 as depicted in FIGS. 7 and 8 are for illustrative purposes only. Any number of lag bolts 34 may be placed in the flanges 12 at any position so as to fit the holes 36 in base plate 11 without departing from the original spirit and scope of the invention.

FIG. 6 further depicts that holes 36 also allow the use of an S-hook 40 that is well known the art to be placed in the base plate 11. Once S-hook 40 is placed in base plate 11 in any of the holes 36 provided, it is used to support and hold additional peripheral devices such as headphones 42 that aid the user in creating music. Also depicted in the embodiment of FIG. 6 is a mini-light 38 which aides the user in viewing the keyboard and other components of the laptop computer. The mini-light 38 is well known in the art and couples to base plate 11 by a standard clamp.

In yet another embodiment of the invention, support rod 32 is inserted into a freestanding adjustable tripod. The term “tripod” carries all of the common meanings and definitions as applied to the prior art and expressly includes all known designs for free standing fixtures without regard to the number of feet or details of structure. The tripod is adjustable so that a guitar player or keyboardist may use a laptop computer while standing, and yet so that a lighting, sound, or video playback operator may use the same computer and mounting surface combination while sitting in a chair.

With regard to the use of this invention in the music field, the stand advantageously can be provided with a finish and/or materials to fit with the “hardware look” of the existing drum market, so that it aesthetically appears as if were an originally intended accessory. However, it should be understood that the invention is not limited to such a field, but can be used in any environment where laptop computers are utilized in conjunction with other apparatus or machinery.

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following invention and its various embodiments.

I claim:

1. An apparatus for mounting a computer, comprising:
a mounting plate having a top surface that is adapted to receive a computer; and,
a support structure with a first and second coupling location;
wherein said first location is coupled to the mounting plate; and,
wherein said second location is configured to be coupled to a structure of a musical instrument.

2. The apparatus of claim 1 further comprising at least one opening in said mounting plate for permitting cooling air to flow beneath a computer received on said top surface.

3. The apparatus of claim 1 further comprising shock absorbing non-slip material on said top surface of said mounting plate so that shock waves produced from playing said musical instrument are absorbed thereby.

4. The apparatus of claim 1 wherein said configuration of the support structure at the second location is defined by a multi-clamp.

5. The apparatus of claim 1 wherein said configuration of the support structure at the second location is defined by a double-ended-clamp.

6. The mount of claim 1 further comprising a light attached to said mounting plate.

7. The mount of claim 1 further comprising:
an upstanding fixed clamping member mounted on said top surface, said fixed clamping member being engageable with a first side of a laptop computer that is received on said top surface;
an upstanding movable clamping member mounted on said top surface, said movable clamping member being movable toward and away from said fixed clamping member and being engageable with a second side of the laptop computer that is received on said top surface; and
adjustment means operating on said movable clamping member for moving said movable clamping member toward and away from said fixed clamping member, whereby the laptop computer received on said top surface can be clamped on said top surface between said fixed clamping member and said movable clamping member wherein said fixed clamping member extends along said first side edge and said movable clamping member extends along said second side edge.

8. The apparatus of claim 7 wherein said adjustment means comprises a flange attached to said mounting plate and a rotatable screw extending through a threaded opening in said flange and in engagement with said movable clamping member.

9. The apparatus of claim 1 wherein the musical instrument type is selected from the group consisting essentially of percussion, wind, or string.

10. The apparatus of claim 1 wherein the musical instrument is a drum-set.

11. The apparatus of claim 10 wherein said drum-set structure is selected from the group consisting essentially of hi-hat stand, snare drum stand, or cymbal stand.

12. A stand for securing a computer, said stand comprising:
a mounting plate; and,
an upstanding structure of a musical instrument coupled to said mounting plate.

13. The stand of claim 11 further comprising shock-absorbing non-slip material on the mounting plate said material for absorbing shock-waves produced by musical instrument.

14. The stand of claim 11 wherein the coupling of said mounting plate to the upstanding structure features a support post.

15. The stand of claim 13 wherein the coupling of said mounting plate to the upstanding structure features a clamp selected from the group consisting essentially of a multi-clamp and double-ended clamp.

16. The portable stand of claim 14 further comprising a light attached to said mounting plate.

17. The portable stand of claim 11 further comprising shock absorbing non-slip material on said mounting plate so that shock waves produced from playing said musical instrument are absorbed thereby.

18. The mount of claim 11 wherein said upstanding structure is selected from the group consisting essentially of hi-hat stand, snare drum stand, or cymbal stand.

19. A method of operating a computer by a musician, said method comprising the steps of:
placing the computer on a mounting plate that is coupled to an upstanding structure of a musical instrument;
positioning the musician in a position to operate the musical instrument; and,
permitting the musician to operate the computer from said position.

20. The method of claim 19 wherein the computer is operated by displaying the musician to at least one member of a social network over the internet.
